(19) United States
(12) Patent Application Publication
(10) Pub. No.: US 2006/0103003 A1
(43) Pub. Date: May 18, 2006

(54) Modular construction component with encapsulation

(76) Inventors: Patric Heide, Vatderstetten (DE); Frank Rehme, Munich (DE)

Correspondence Address: FISH & RICHARDSON PC, P.O. BOX 1022, MINNEAPOLIS, MN, 55440-1022, US

(21) Appl. No.: 10/541,911

(22) PCT Filed: Jan. 12, 2004
(86) PCT No.: PCT/EP04/00150

§ 371 Date: Aug. 30, 2005

(30) Foreign Application Priority Data
Jan. 13, 2003 (DE) 103009582

(51) Int. Cl. H01L 23/12

(52) U.S. Cl. 257/700

(57) ABSTRACT

The invention concerns an ultrahigh frequency module, in particular a microwave or millimeter wave module, as well as a technique for housing such parts. The ultrahigh frequency module contains, for example, a) an active individual component, that in particular includes a diode, a transistor or an integrated circuit, and b) a substrate with multi-layer construction and integrated circuit elements, the individual components being located on the upper side of the substrate. It is suggested that a film cover be used to protect the individual ultrahigh frequency components.

The invention concerns in particular an ultrahigh frequency module, for example, a microwave or millimeter wave module, as well as a method for housing such parts.

The frequency range between 1 GHz and 30 GHz is called the microwave range (MW range). The frequency range from 30 GHz upward is called the millimeter wave range (mmW range). The ultrahigh frequency modules differ from the high frequency modules in particular by the fact that, as a rule, “waveguides,” for example, microstrip lines and coplanar lines, are used for ultrahigh frequency circuits starting at 5 GHz.

The ultrahigh frequency modules are integrated electronic constructional units that perform various functionalities for applications used in the frequency range between 1 and 100 GHz. In general, such modular units can be used for data transmission systems, for example, for TV satellite reception, for wireless local data networks—LANs (local area networks), WLANs (wireless LANs), Bluetooth, optical modules such as multiplexers, modulators and sender-receiver units—as well as for radar, for example automobile radar at 24 GHz and 77 GHz, and for front-end modules for broadband communication, for example, LMDSs (local multimedia distribution systems) and radio relay systems for base stations.

Today, modules that are to be used in the millimeter wave range are mostly produced using thin-film substrates. The thin-film substrate can carry one or more chip modules at the same time. The chip modules are fastened to the substrate with wire bonds or by using the flip-chip technique and are electrically connected with it.

Furthermore, there are, microwave or millimeter modules that contain a ceramic substrate on which microwave or millimeter wave chips are mounted without housing. Together with the chip modules, the substrate is enclosed in a metal or ceramic housing and connected electrically via ultrahigh frequency ducts with external circuits. This technique requires very expensive housing designs. Such modules are heavy and need a large amount of space.

An existing alternative is construction of the mmW-circuit with the help of the well-known SMD technique (SMD=surface mounted device). Whereas, when the modular method is used, it is the circuit constructed from modular units that is enclosed in a housing, the SMD technique uses modular units that are already encased. Because of that, the need for a housing is eliminated to a very large extent. Application of this technique is limited because of rising losses and fluctuations in the transmission characteristics owing to the comparatively larger manufacturing tolerances of the circuit in the direction of higher frequencies. Moreover, it also needs a large amount of space.

A further alternative is offered by the substrate-integrated housings, as they are called. In these, the substrate takes over tasks of the housing. The housing then consists of the substrate, side walls (on the substrate) and a covering on the side walls. There are forms of such housing in which the side walls are first connected with the substrate, and, then, after the circuit has been assembled (the modules attached), a metal sheet, for example, is welded on, as well as forms in which a cap (a covering with side walls) is mounted on the substrate after the components have been attached to it. This technique has the disadvantage that the outer dimensions of the module are determined by the geometry of the pre-fabricated housing.

It is known that in the manufacture of high frequency modules, for example, mobile radio modules, relatively inexpensive processes and materials are used compared with ultrahigh frequency modules:
a) The chip & wire technique, in which the chip is mounted on the substrate with its back side facing the substrate and bonded with wire bonds. For mechanical stability, a sealing compound (for example, Globtop) is also poured over the chip.
b) The flip-chip technique, in which the mounted chip can be stabilized mechanically and insulated with a sealing compound (Underfiller/Globtop).

Both methods are unsuitable for ultrahigh frequency applications, inasmuch as, for example, the masses of sealing compound mentioned above significantly influence (attenuate) wave propagation in the microwave range.

In addition, there is the CSSP technology (CSSP=chip size SAW package; SAW=surface acoustic wave), which is used with modules that work with acoustic surface waves (SAW components); see, for example, publications EP 0900477A and EP 0759231A. When the SAW modules are enclosed, one takes care that the acoustic surface does not come into contact with the sealing compound, since in that case the speed of propagation of acoustic waves and consequently the electrical characteristics of the SAW modules are strongly influenced. For such modules, it is possible, for example, to prevent contact between the sealing compound and the acoustic structures that conduct the signal by means of a protective cap made of plastic that is mounted on the side of the chip that has the active structures. A further possibility consists in encapsulating the SAW chips by means of a protective foil which covers the SAW chip from the back side (EP 1093159A). Up to now, these methods have only been applied for housing SAW components. The SAW modules have the disadvantage that they cannot be made for ultrahigh frequency ranges above 2 GHz because of the technologically conditioned minimum interval of the acoustic finger structures (finger periods) and because of increasing volume wave losses with increasing frequency.

It is the purpose of the present invention to describe a microwave or millimeter wave module with active individual components which assures electrical connections between various module components, as well as protection of the module components, in particular the ultrahigh frequency components of the modular unit, from external influences, such as dust, mechanical damage and moisture, without attenuation of the ultrahigh frequency signals.

The present invention achieves this goal by means of a modular unit with the characteristics of claim 1. Embodiments of the invention that offer advantages follow from additional claims.

The invention presents a modular unit working in the ultrahigh frequency range that contains:
a substrate with at least two dielectric layers, with at least one integrated (in particular passive) circuit element, with at least one conducting structure on the upper side and at least one external contact on the bottom side,
at least one active individual component that is located on the upper side of the substrate,
at least one film covering, which completely covers at least one active single component and serves to protect at least one individual component from dust, moisture and mechanical influences.

In doing so, the film covering seals tightly with the upper side of the substrate. The film covering serves in particular to protect the parts that conduct the ultrahigh frequency signals of the individual components from dust, moisture and mechanical influences.

Together, the film covering, the individual component and the substrate form an enclosed space.

Preferably, all electrical connections—for example, bumps or bond wires—between chip and substrate are located in this space and do not come into contact with the film covering. Furthermore, all structures of the module described by the invention that conduct the ultrahigh frequency signal and that are positioned on the upper side of the substrate and on the upper or lower side of the individual component, are located in the enclosed space and are thus protected from stress of the material and from external influences.

In the preferred variation of the invention, one side of the individual component has at least one active ultrahigh frequency structure that lies bare. The active ultrahigh frequency structure that lies bare is located in the enclosed space and does touch the film covering.

The interface between substrate and chip in a modularly constructed unit, in particular such a unit that works in the ultrahigh frequency range, is susceptible to an undesirable attenuation of the signal, as the transmission characteristics of exposed signal connections are impaired by fouling or contact with an encapsulating mass of sealing compound. Because of that, the placement of the exposed structures of a module (active circuit components, electrical connections) that conduct the ultrahigh frequency signal in an enclosed space has the advantage that the signal's electromagnetic wave is not attenuated by undesired contact with, for example, a mass of sealing compound. The modular unit in accordance with the invention is thus distinguished by particularly low insertion attenuation.

By a passive circuit element is understood, in particular, an inductance, a capacitance, a line, for example, a connecting line, or a segment of a line. These can be located in a well-known manner as conductor paths between, in and on dielectric layers of a substrate with multiple-layer construction and thus constitute integrated circuit elements. Vertical connections between the conductor paths in different layers (interlayer connections), also count as integrated circuit elements, inasmuch as they serve to guide the signal vertically on the one hand, and on the other hand, they also constitute, in particular for ultrahigh frequencies, a (parasitic) inductance as well as a (parasitic) capacitance. Together, individual integrated circuit elements form integrated circuits, in particular passive circuits, such as those of a filter or of a mixer. Further, integrated circuit elements can constitute at least one part of at least one active circuit, which part is electrically connected with active individual components on the surface of the substrate.

In the case of ultrahigh frequencies, in particular in the mmW range, capacitances and inductances are often present in the form of distributed elements made out of line sections. The capacitances can be constructed as radial stubs.

By an active individual component is understood a discrete, non-linear or active circuit element, such as a diode or a transistor, or a chip module including at lease one active component, with or without a housing.

The active individual component that is constructed as a chip module can be a microwave chip, a millimeter wave chip or an IC module (IC=integrated circuit). The IC module can, in turn, be a MMIC module (MMIC=monolithic microwave integrated circuit).

The active individual components can, for example, be constructed on the Si, the SiGe-, the GaAs- or the InP basis.

The active individual component has external contacts to the electrical connection with the integrated circuit elements integrated in the substrate.

The upper side of the substrate bears at least one conducting structure, which consists, in particular, of at least one contact for establishing the electrical connection between the integrated circuit elements in the substrate and the at least one active individual component on the upper side of the substrate, a connection line between active individual components or a portion of a circuit that is, for the most part, integrated into the substrate.

The under side of the substrate has external contacts for making the electrical connection, for example, with the printed circuit board of a terminal.

The at least one active individual component, in particular a MMIC module that comprises, for example, a frequency divider circuit, a frequency multiplier circuit, an amplifier circuit, an oscillator circuit or a mixer circuit, will be connected mechanically or electrically, in the ultrahigh frequency range that is relevant for the invention with the substrate and the integrated circuit elements, preferably using the flip-chip technique, so that the side (structured side) of the integrated circuit elements that bears the active ultrahigh frequency components faces the upper side of the substrate.

In addition to the at least one individual active component, one or more discrete modules (for example, a coil, a capacitor or a resistor), as well as one or more substrates with passive HF structures, such as filters or mixers, in particular substrates that have been structured by means of the thin-film technique, can be located on the upper side of the substrate.

The film covering consists of a film whose form is (or will be) adapted to the components to be protected (or covered). The film covering lies over the rear side of the active individual components and on all sides is in tight contact with the surface of the substrate so that the active individual components are completely covered and thus are protected from external mechanical influences, dust and moisture. In this manner, several active ultrahigh frequency individual components, as well as at least one ultrahigh frequency individual component together with at least one other digital or low frequency individual component, can be encapsulated together or individually. Preferably, the film covering covers all individual components that are located on the upper side of the substrate.

A module that is encapsulated in accordance with the invention distinguishes itself with respect to the state of the art by low electrical losses in the ultrahigh frequency range, in particular in the millimeter wave range, that are due to the housing method. In contrast to the conventional housings that are integrated with the substrate, encapsulation with the help of a moldable film has the advantage that the outer dimensions of the ultrahigh frequency module in accordance with the invention are determined primarily by the dimensions of the individual components that are located on the upper side of the substrate, as well as by the thickness of the film covering. Moreover, the advantageous encapsulation assures a high quality of the ultrahigh frequency components with respect to their reliability and transmission characteristics. In advantageous embodiments, electrical connections of the individual components not only with one another, but also with external high frequency, low frequency and electric power supply circuits, are provided in the modular units in accordance with the invention. In addition, it is possible to achieve a high degree of integration through the vertical positioning of integrated circuits in the multi-layered substrate of the module, which takes up a small amount of space.

In the following, the invention will be explained in more detail by using exemplary embodiments and the schematic figures pertaining to them that are, being schematic, not drawn to scale.

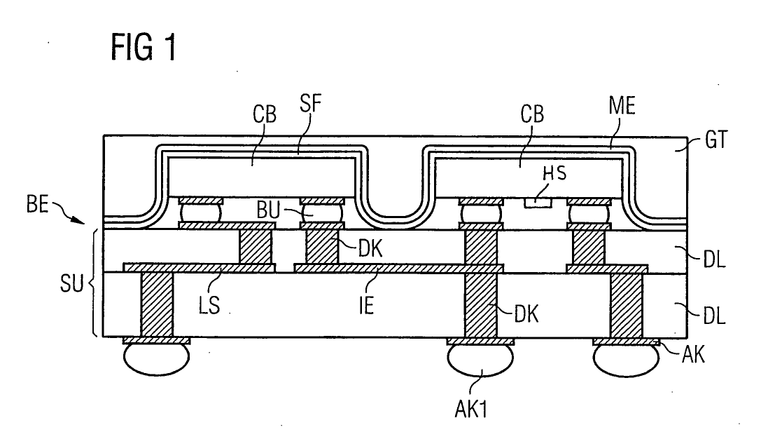

FIG. 1 shows a modular unit in accordance with the invention in schematic cross section

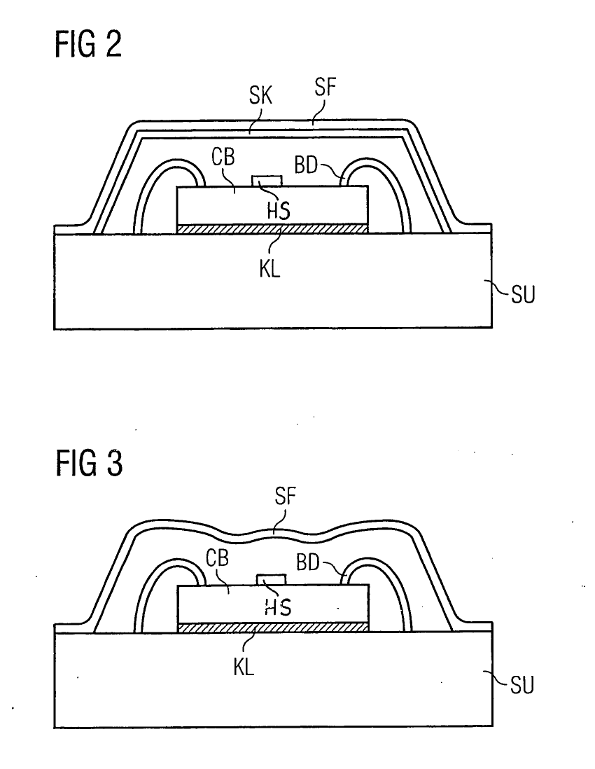

FIGS. 2 and 3 show advantageous embodiments of the modular unit in accordance with the invention in schematic cross section

In FIG. 1, the general characteristics of the invention are shown by means of a schematic cross sectional presentation of a modular unit in accordance with the invention.

FIG. 1 shows the schematic cross section of a modular unit, BE, that is in accordance with the invention, with two active individual components, CB, and a multi-layered substrate, SU. Here, the active individual components, CB, are chip modules that include at least one active circuit element (one active ultrahigh frequency structure, HS, in particular a diode or a transistor), this active ultrahigh frequency structure, HS, being located on one side of the individual component, CB, and being exposed. The ultrahigh frequency structure, HS, is located in a enclosed space which is formed by the substrate, SU, the individual component, CB, and the film covering, SF. In the variation of the invention that is presented in FIG. 1, the ultrahigh frequency structure, HS, is located on the bottom side of the individual component, CB, and faces the upper side of the substrate.

The active individual component, CB, is electrically connected via bumps, BU, with integrated circuit elements, IE, that are hidden in the multi-layered substrate, SU (flip chip technique). The substrate, SU, has conductor structures on the upper side for establishing the afore-mentioned electrical contact, as well as exterior contacts, AK, on the bottom side for establishing an electrical connection with the printed circuit board of a terminal. The exterior contacts, AK, can be constructed as land grid arrays (LGA) or additionally furnished with balls of solder, AK1 (μBGA, or ball grid arrays). Needle-shaped external contacts (leads) and non-galvanic transitions between the modular unit and the printed circuit board that is to be connected externally, such as, for example, waveguide transitions or slotted couplings are also possible. The vertical signal transmission in the substrate, SU, takes place via interlayer connections, DK.

A modular unit in accordance with the invention is preferably constructed in a modular manner and has several individual components, CB, that are located on the same substrate, SU, and that are all fully covered with a common film covering, the film covering preferably encapsulating each individual component individually, so that each individual component is provided with its own enclosed space. However, it is also possible that the film covering form only one enclosed space in which several or all individual components of the module are located.

In the advantageous example of an embodiment of the invention shown in FIG. 1, both active individual components, CB, are covered with a film, SF, (film covering). The covering of the individual components with film is referred to as lamination. During lamination, the film is permanently shaped. Preferably, the film cover is made of a polymer that has especially low water absorption, for example, fluoride-based polymers such as polytetrafluoro-ethylene (PTFE) or polyolefins such as (cross-linked) polypropylene or polyethylene. Additionally, the film cover can consist of a metal and be fiber- or particle-filled. Moreover, the film cover can be metal- or ceramic-coated as shown in the figure.

To achieve screening from the surroundings, the film covering is additionally covered with a metal coat, ME. This coat can, for example, be applied by means of galvanizing, chemical metal precipitation, steaming or a combination of the procedures mentioned. For mechanical stabilization, the individual components that are located on the upper side of the substrate in this exemplary embodiment are covered with a sealing compound, GT. It is possible to omit this mass of sealing compound, if so desired. Here, mass of sealing compound means all substances that are applied to the film in liquid state and that become hard through curing (chemical reaction) or solidification (cooling). This includes compounded and non-compounded polymers such as liquid insulating substances, Glob-Top, thermoplastic resins or plastic adhesives, as well as metals or ceramic materials, such as ceramic adhesives. Glob-Top is a sealing material that spreads out very little because of its high viscosity, and which therefore encloses in a drop-like manner the individual component that is to be protected.

In the embodiment of the invention that is shown in FIG. 1, the metal-coated film is covered with a sealing compound after lamination. In a different embodiment, it is possible to put the metal coat not on the film covering, but on the sealing compound.

In an advantageous embodiment of the modular unit in accordance with the invention that has a ceramic substrate, the film is partially removed at the edges adjoining the substrate—for example with lasers—and coated with metal only afterwards so that the individual components that are to be covered are enclosed completely by metal or ceramic are thus hermetically sealed off.

Together with the substrate, SU, and the individual component, CB, the film covering forms an enclosed space in which the parts of the individual component that conduct the ultrahigh frequency signal and that are to be protected, are located, in particular the electrical connections and the exposed active ultrahigh frequency structures. In all forms of the invention's embodiment, the film covering does not come in contact with the electrical connections or the ultrahigh frequency connections (bumps) that conduct the signal between the chip and the substrate. The ultrahigh frequency connections are protected by the film covering in such a way that the electromagnetic wave (i.e., the ultrahigh frequency signal), is not influenced by, for example, environmental influences or a stabilizing mass of sealing compound.

Here, ‘substrate’ means all types of planar circuit bearers. These include ceramic substrates (thin-film ceramic, thick-film ceramic, LTCC=low temperature cofired ceramics, HTCC=high temperature cofired ceramics; LTCC and HTCC are ceramic multi-layer circuits), polymer substrates (conventional printed circuit boards such as FR4, so-called soft substrates whose polymer base consists, for example, of PTFE=Teflon or polyolefins and that are typically reinforced with glass fiber or are filled with ceramic powder), silicon as well as metallic substrates in which metallic conductor paths and a metal base plate are insulated from one another with polymers or ceramic materials. Here, ‘substrate’ also refers to molded interconnection devices (MID) that consist of thermoplastic polymers on which conductor paths are structured.

The bumps, BU, serve to establish an electrical connection between the integrated circuit elements, IE, that are hidden in the substrate, SU, and the at least one active individual component, CB, and perhaps the additional individual components that are located on the upper side of the substrate. Usually the bumps are made of solder, for example, SnPb, SnAu, SnAg, SnCu, SnPbAg, SnAgCu in varying concentrations or of gold. If the bump is made of solder, the component is connected to the substrate by soldering, if it is made of gold the individual components, CB, and the substrate, SU, can be connected by thermo compression bonding, ultrasonic bonding or thermo-sonic bonding (sinter or ultrasound welding procedure). For ultrahigh frequency applications, the height of the flip-chip bumps must be kept so low that only a small amount of the electromagnetic radiation coming from the ultrahigh frequency individual component can be absorbed by the laminated film. One possibility of attaining a low height of the flip-chip bumps is offered, in particular, by thermo compression bonding.

In another embodiment of the invention, the active individual components can be SMD components.

Besides active individual components, it is possible to also mount passive individual components, in particular discrete coils, capacitors, resistors or individual chips with passive circuits (for example, filters, mixers, adapting circuits) on the upper side of the substrate. It is possible to compensate for the detuning of the module by the housing with additional discrete passive compensation structures.

The passive individual components, as well as the integrated circuit components, can form at least one part of the following circuits: a high frequency switch, an adapting circuit, an antenna, an antenna switch, a diode switch, a high-pass filter, a low-pass filter, a range-pass filter, a range-blocking filter, a power amplifier, a diplexer, a duplexer, a coupler, a directional coupler, a storage element, a balun or a mixer.

Moreover, the function of the integrated circuit elements, including the interlayer connections and the link circuits, can be limited exclusively to the electrical signal duct.

The passive individual components can be connected electrically or mechanically with the substrate by means of, for example, the flip-chip technique, the die & wire bond technique (see, for example, FIG. 2) or by the SMD technique.

So that the bond wires, BD, do not come in contact with the film covering when the die & wire technique is used, the individual components can have a rigid protective cap, SK; see FIG. 2. When this connecting technique is used, the individual component is attached to the substrate, SU, with cement or with solder, KL. The bond wires can be made of steel tape (tape bonds) instead of being made of gold or aluminum wires with a round cross section.

In this variation of the invention, the ultrahigh frequency structure, HS, of the invention is located on the upper side of the individual component, CB, and faces away from the substrate, SU.

Furthermore, the module in accordance with the invention can contain at least one additional individual component that is not shown here. With the film covering—preferably one that is non-deformable—several individual components can be encapsulated in a common space. But it is also possible that a non-deformable film covering be structured in such a way that it has several cap-like areas, each of which provides its own closed-off space for each individual component and seals tightly with the substrate so that each individual component is individually encapsulated.

FIG. 3 shows an additional advantageous embodiment of the invention. In this case, during lamination, the film is not put under pressure at the place where the film covers the individual component that is to be protected—for example, by placing a protective cap over it or by cavities molded into the film over the afore-mentioned individual component. The film is, then, not drawn closely over the individual component, but lies loosely over it, so that sensitive or deformable parts of the individual component do not need to be protected.

If the active individual component does not have any signal-conducting structures requiring protection on the surface (for example, all circuit elements and circuits are hidden in a multi-layered substrate), it is then possible to first cover this individual component with the sealing compound and to apply a film covering only after the sealing compound has hardened.

The signal lines in the modular unit in accordance with the invention can either be completely hidden in the substrate or at least a part of the signal lines can be located on the upper side of the substrate.

To facilitate understanding, the invention was illustrated using only a few exemplary embodiments, but it is not limited to these. Additional possibilities of variations are given by other relative positionings of individual components, the film covering, the sealing compound and the metal coat that are different from those shown in the presented embodiments. Further, there are other possibilities with respect to the connection technique between the individual components and the substrate, as well as between the substrate and an external printed circuit board.

1-21. (canceled)

22. An ultrahigh frequency module comprising:
a substrate having multiple layers, the substrate comprising:
dielectric layers;
at least one circuit element;
at least one conducting structure on an upper surface of the substrate; and
at least one exterior contact on a bottom surface of the substrate, at least one active component located on the upper surface of the substrate and electrically connected with at least one circuit element; and
at least one film covering to cover at least one active component.

23. The module of claim 22, wherein the at least one active component comprises one of more of the following: a diode and a transistor.

24. The module of claim 22, wherein the at least one active component comprises a microwave chip, a millimeter wave chip or an integrated circuit module.

25. The module of claim 24, wherein the integrated circuit module comprises a microwave module.

26. The module of claim 22, wherein the at least one active component is electrically and mechanically connected to the substrate via a flip-chip connection, a wire-bond connection or a surface mounted device connection.

27. The module of claim 22, further comprising:
at least one passive component comprising one or more of the following: a coil, a capacitor, a resistor, or a chip with a passive circuit.

28. The module of claim 22, further comprising:
at least one passive component comprising one or more of the following: a filter and a mixer switch.

29. The module of claim 22, wherein the at least one active component is encapsulated by a sealing compound.

30. The module of claim 22, wherein the dielectric layers comprise at least two layers formed by low temperature cofired ceramic or high temperature cofired ceramic.

31. The module of claim 22, wherein the at least one circuit element comprises an inductor, a capacitor, a linking circuit, or a circuit connecting layers of the substrate.

32. The module of claim 22, wherein the at least one circuit element is part of a circuit having passive functionality.

33. The module of claim 22, wherein the at least one circuit element is part of an adaptive circuit.

34. The module of claim 22, further comprising signal lines, the signal lines being inside the substrate.

35. The module of claim 22, further comprising signal lines, a portion of the signal lines being located on an upper surface of the substrate.

36. The module of claim 22, wherein the film covering comprises a polyimide.

37. The module of claim 22, wherein the film covering comprises a metal.

38. The module of claim 22, wherein the film covering covers all active components located on the upper surface of the substrate.

39. The module of claim 22, wherein the film covering forms a seal with the upper surface of the substrate such that the film covering, the at least one active component, and the substrate together form an enclosed space.

40. The module of claim 38, further comprising: at least one electrical connection located within the enclosed space and not being in contact with the film covering, the at least one electrical connection for electrically connecting at least one active component with at least one circuit element.

41. The module of claim 38, further comprising:
an active ultrahigh frequency structure located on one of the active component within the enclosed space and not in contact with the film covering.
